(19) United States
(12) Patent Application Publication
(10) Pub. No.: US 2017/0217767 A1
(43) Pub. Date: Aug. 3, 2017

(54) THROUGH SUBSTRATE VIAS USING SOLDER BUMPS

(71) Applicant: Innovative Micro Technology, Goleta, CA (US)

(72) Inventors: Christopher S. GUDEMAN, Lompoc, CA (US); Stuart Hutchinson, Goleta, CA (US)

(73) Assignee: Innovative Micro Technology, Goleta, CA (US)

(21) Appl. No.: 15/415,919

(22) Filed: Jan. 26, 2017

Related U.S. Application Data
(60) Provisional application No. 62/288,716, filed on Jan. 29, 2016.

(51) Int. Cl. B81C 1/00

(52) U.S. Cl. CPC B81C 1/00301

(57) ABSTRACT

A through substrate via is formed by disposing a quantity of solder material at the top of a through hole formed in a substrate, coating the hole with a wetting layer, and melting the solder material such that it flows into the hole. The solder material may alloy with the wetting layer, freezing upon formation of the alloy. Subsequent processing steps may be performed at temperatures higher than the melting point of the solder material.

### CROSS REFERENCE TO RELATED APPLICATIONS

This US nonProvisional Patent Application is based on and claims priority to U.S. Provisional Application Ser. No. 62/288,716, filed Jan. 29, 2016.

### STATEMENT REGARDING FEDERALLY SPONSORED RESEARCH

Not applicable.

### STATEMENT REGARDING MICROFICHE APPENDIX

Not applicable.

### BACKGROUND

This invention relates to vias that are formed completely through a silicon substrate.

Microelectromechanical systems (MEMS) are very small moveable structures made on a substrate using lithographic processing techniques, such as those used to manufacture semiconductor devices. MEMS devices may be moveable actuators, sensors, valves, pistons, or switches, for example, with characteristic dimensions of a few microns to hundreds of microns. One example of a MEMS device is a microfabricated cantilevered beam, which may be used to switch electrical signals. Because of its small size and fragile structure, the movable cantilever may be enclosed in a cavity to protect it and to allow its operation in an evacuated environment. Therefore, upon fabrication of the moveable structure on a wafer, (device wafer) the device wafer may be mated with a lid wafer, in which depressions have been formed to allow clearance for the structure and its movement. To maintain the vacuum over the lifetime of the device, a getter material may also be enclosed in the device cavity upon sealing the lid wafer against the device wafer.

In order to control such a microfabricated elements, electrical access must be provided that allows power and signals to be transmitted to and from the elements. Previously, these signal lines were routed under the bond lines between the lid wafer and the device wafer. Because the enclosed elements may be delicate, the bondlines may be, for example, metal alloy bondlines that are activated at relatively low processing temperatures. However, the presence of the flat metal bondlines directly adjacent to potentially high frequency signal lines may cause unwanted capacitance in the structure, limiting its high speed performance.

Accordingly, performance advantages can be realized by forming the electrical connections using through substrate vias. Various methods have been developed to manufacture such TSVs.

Fundamentally, holes must be etched through the wafer, using wet or dry etch processes, LASER or mechanical drilling. Then the via must be filled with conductive material. Fill materials include but are not limited to copper, gold, and doped polysilicon.

Vendors in the through-substrate via market have each pursued their own solution to fabrication. Each solution carries large cost overhead in via fill and auxiliary processes necessary to complete the via wafer. Particularly high cost is encountered when the application demands a high quality, void-free, low resistance via (typically for high-frequency applications).

Prior art is shown in FIG. 1, Indicating 4 of the common methods currently employed to achieve through-substrate vias. Beginning with a wafer with via hole already formed, FIG. 1a shows a via generated using LPCVD deposited, doped polysilicon. This is a machine-time intensive method of via formation and yields a relatively high-resistivity via unsuitable for high-frequency applications. FIG. 1b shows a via formed by the vacuum deposition (and possibly partial-electroplating) of a conductive metal. While acceptable for high frequency applications, the hole through the wafer obviates any further processing. FIG. 1c shows the lowest resistance via, formed by the electroplating of metal on a vacuum-deposited seed layer such that the entire via is filled, with low resultant resistance and high suitability for high frequency applications. Problems with this technique include void formation with large aspect-ratio vias, and excessive time and cost in the electroplating tool, a single-wafer process. FIG. 1d shows the formation of a via using the highly-doped wafer as the conductor. The original holes are filled with insulator, in the case of silicon, normally silicon oxide.

Accordingly, microfabricated high frequency through substrate electrical via structures have posed an unresolved problem that prior art methods have been unable to adequately address.

### SUMMARY

We describe here a method of via-fill with a variety of materials, using the example of gold-tin solder, to achieve a low-resistance via suitable for a variety of high-frequency and DC applications.

We describe a method of via formation starting with the via hole wafer of FIG. 1, using a solder-bumping tool to deposit metal at the via site. In some embodiments, 80/20 Au/Sn solder may be used, but the invention encompasses all solder alloys.

Conventional use of a solder bumping tool involves jet-deposition or screen-printing of the solder ball on a metal pad on the wafer and heating of the deposited solder to assist in adhesion of the ball. Note that these same balls are currently used to bond devices to the wafer, so tooling and processes are well established.

The invention consists of pre-metallization or “wetting” layer (coating via walls with metal) of the via using a vacuum deposition technique, jet-deposition or screen-printing of the solder at the via site, achieving partial via fill and formation of a mass of solder over the via, and reflow of the solder mass within the bumping tool with heat, pulling the solder into the remainder of the unfilled via by reflow and alloying of the pre-metallization wetting layer with the solder. If necessary, further reflow can be performed by the end user in a furnace, or wafer bonding tool.

Improvement over prior art is achieved due to use of a common, inexpensive, volume-production tool (solder bumping tool) to achieve low-resistivity, high frequency compatible, void-free through wafer vias, resulting in a cost reduction of approximately an order of magnitude in the via fill process.

A feature of this process is that conductive vias are formed in a relatively insulative surrounding material of the substrate. These vias may supply power and signals to/from the component inside a hermetically sealed device cavity. The signal and/or power may be delivered to the sealed device cavity with a through substrate via (TSV). The TSV may have a bonding pad on one side of the substrate, and a conductive line leading to the device within the device cavity. Accordingly, this architecture avoids the large capacitive losses that may occur with the under-bond routing of these electrical leads.

The encapsulated components may include integrated circuits (ICs) or MEMS devices, such as turning mirrors, optical elements, electrical switches, sensors and actuators for example.

Numerous devices can make use of the systems and methods disclosed herein. In particular, high speed, compact telephone or communications switching equipment may make use of this architecture. RF switches benefit from the reduced capacitive coupling that an insulative substrate can provide. High density vias formed in the insulative substrate increase the density of devices which can be formed on a substrate, thereby reducing cost to manufacture. The performance of such devices may also be improved, in terms of insertion loss, distortion and isolation figures of merit.

These and other features and advantages are described in, or are apparent from, the following detailed description.

### BRIEF DESCRIPTION OF THE DRAWINGS

Various exemplary details are described with reference to the following figures, wherein:

FIG. 1a-1d are a schematic illustrations of prior art methods for forming through substrate vias;

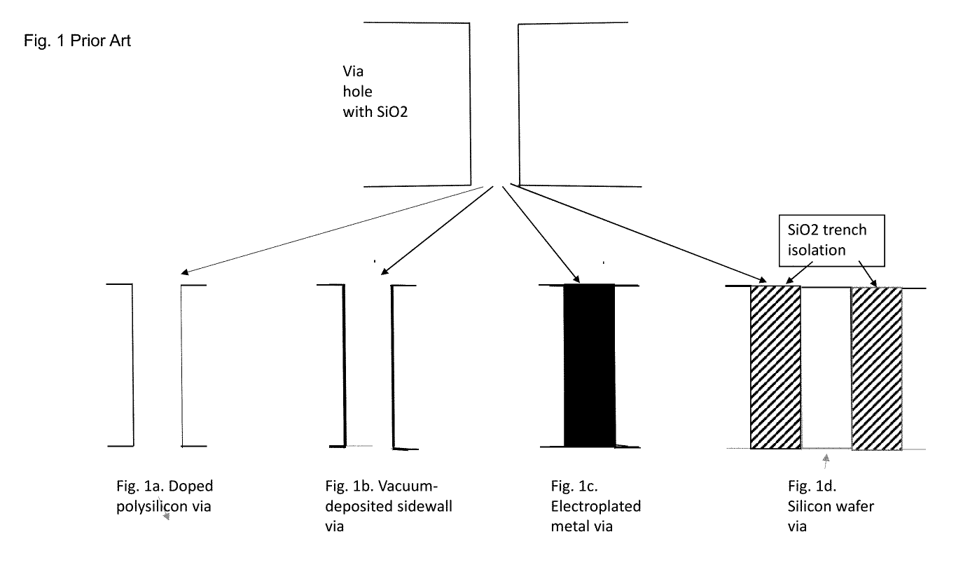

FIG. 2a-2c are schematic cross sectional illustration of the first three steps of the exemplary method for forming through substrate vias;

FIG. 3 is a schematic, cross sectional illustration of a fourth step of the exemplary method for forming through substrate vias;

FIG. 4 is a schematic, cross sectional illustration of a fifth step of the exemplary method for forming through substrate vias;

FIG. 5 is a schematic, cross sectional illustration of a sixth step of the exemplary method for forming through substrate vias; and

FIG. 6 is a schematic, cross sectional illustration of a through substrate via providing electrical access to a plurality of microfabricate devices in a cavity.

It should be understood that the drawings are not necessarily to scale, and that like numbers may refer to like features.

### DETAILED DESCRIPTION

The systems and methods described herein may be particularly applicable to microfabricated electro mechanical systems (MEMS) devices, wherein small, generally movable devices are formed on a substrate surface and enclosed with a lid wafer to protect them in an encapsulated device cavity. Some devices, such as infrared detectors and emitters, may require a vacuum environment, such that the device cavity may need to be hermetically sealed. The signal and power lines may be delivered to the sealed device cavity with a through substrate via (TSV). The TSV may have a bonding pad on one side of the substrate, and a conductive line leading to the device within the device cavity.

Through substrate vias may be particularly convenient for MEMS devices, because they may allow electrical access to the encapsulated devices. Without such through holes, electrical access to the MEMS device may have to be gained by electrical leads routed under the lid wafer which is then hermetically sealed. It may be problematic, however, to achieve a hermetic seal over terrain that includes the electrical leads unless more complex and expensive processing steps are employed. This approach also makes radio-frequency applications of the device limited, as electromagnetic coupling will occur from the metallic bondline residing over the normally oriented leads. Alternatively, the electrical access may be achieved with through-wafer vias formed through the handle wafer, using the systems and methods described here.

The systems and methods described herein may be particularly applicable to vacuum encapsulated MEMS devices, such as turning mirrors, optical elements, electrical switches, sensors and actuators for example. However, they may also be applicable to any integrated circuit formed on a device wafer and encapsulated with a lid wafer.

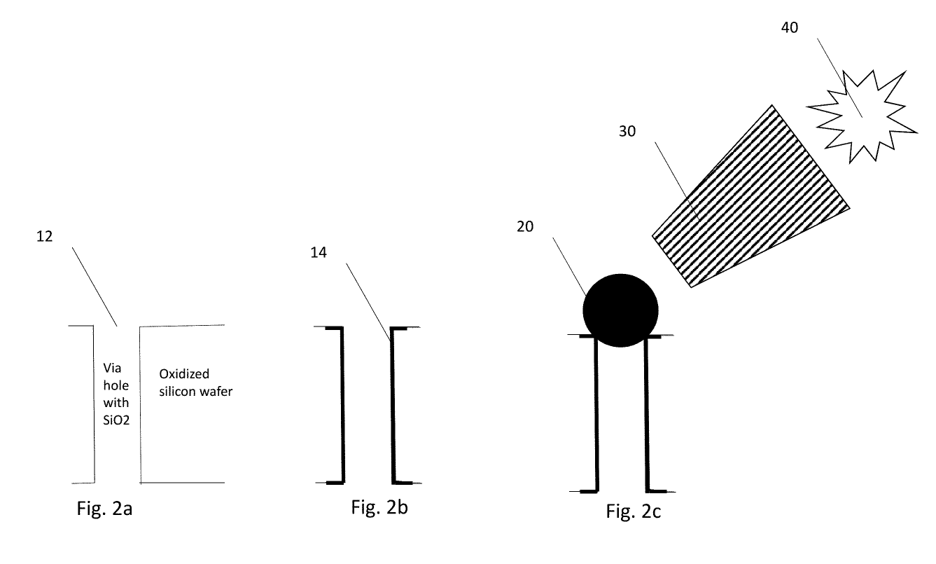

FIG. 2a-2c are schematic cross sectional illustrations of the first three steps of the exemplary method for forming through substrate vias. In FIG. 2a, a through hole 12 may be made in a silicon substrate. The hole 12 is then oxidized by, for example, placing the substrate in a furnace with a moist environment. Methods for oxidizing silicon are well known in the art. This oxidation may result in a thin layer, less than for example, 500 nm on the exposed surfaces of the silicon substrate and the through hole 12.

The through hole 12 may have a width of around 15-50 microns, or even up to about 100 microns. The through hole may have a depth of about 150-250 mircons. Accordingly, the hole 12 may have an aspect (depth/width) ratio in the range of about 1:1 to about 20:1. More typically, the aspect ratio may be about 10, and the hole may have a diameter of about 50 microns.

In the step depicted in FIG. 2b, a pre-metallization wetting layer is deposited conformally over the surfaces of the through hole 12. The wetting layer may be, for example, a layer comprising at least one of gold, palladium, platinum, copper or tin. The layer may be, for example, on the order of 200 nm thick, and may be deposited by electroplating, for example. The wetting layer 14 may therefore be deposited by electroplating conformally over the hole 12. Alternatively, the wetting layer 14 may be deposited by at least one of sputter deposition, chemical vapor deposition, and low pressure CVD, and plasma enhanced CVD.

Prior to the deposition of the wetting layer, a seed layer or adhesion layer may be deposited over the surface. This adhesion layer may by a thin layer of titanium, or titanium-platinum or titanium tungsten, or titanium-nickel. In any case, this adhesion layer may be relatively thin, on the order of 10 nm or less.

FIG. 2c, a solder ball 20 may be placed at the top of the through hole 12. The solder ball may comprise, for example, at least one of lead, tin, indium, silver, germanium, aluminum, gold, or copper. In particular, the solder ball may comprise a eutectic alloy of gold-tin (AuSn) or gold-indium (AuIn) or tin-silver-copper (SnAgCu, also known as SAC), which is a lead free alloy commonly used as solder.

The solder ball may be placed pneumatically, or through screen printing, or with a pick and place machine for example. If using screen printing, the whole wafer or substrate may be covered with solder balls and then pushing the balls through the screen, where the screen has through holes in the appropriate locations. Accordingly, screen printing may be a fast and inexpensive wafer-level process. In other embodiments, the solder ball 20 may be placed in the hole by a pneumatically controlled nozzle 30, which is coaxial with a laser light source 40. In yet another embodiment, the solder material may be fed as a wire through a coaxial laser and placement nozzle, wherein the pulsed laser is used to cut the wire by melting it at brief intervals. The severed metal is then deposited over the top of the hole 12. In yet another embodiment, the solder ball 20 may be disposed in the hole by a pick-and-place machine, well known in semiconductor manufacturing. The situation may be as shown in FIG. 2c, wherein the jet 30 has deposited the solder ball 20 using the bumping tool. Accordingly, the solder ball 20 may be disposed over the hole with a jet of forced air. But in any case, the solder ball 20 may rest at the top of the hole 12 and be held in place by gravity.

The solder ball may be, for example, 80/20 alloy of Au—Sn with a melting point of around 260 degrees centigrade. The solder ball may have dimensions on the order of 50-200 microns in diameter.

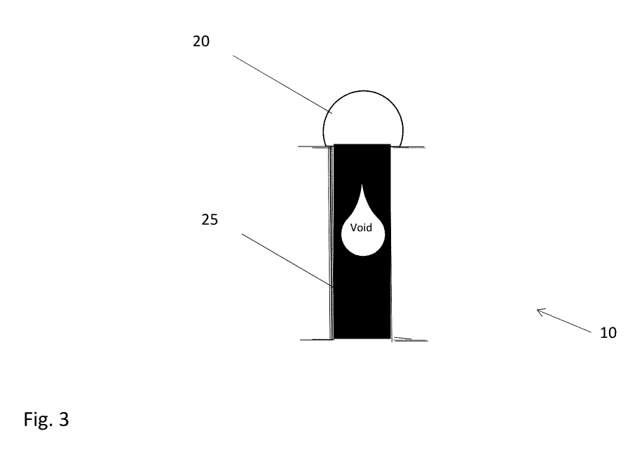

FIG. 3 is a schematic, cross sectional illustration of a fourth step of the exemplary method for forming through substrate vias. In the third step, the solder ball 20 may be melted by a source of heat. In some embodiments, the heat source may be radiation applied by the coaxial laser 40. The laser source 40 may be a pulsed laser source, such that the heat is applied to the solder ball rapidly, but for a short period of time. This may avoid heating large sections of the substrate on which delicate structures may have been fabricated.

In other embodiments, the heat may be a heat gun or a furnace for example. In yet other embodiments, the solder ball may be melted during a rapid thermal anneal (RTA) process step. In any case, sufficient heat may be applied to melt the relatively low melting point solder, such that molten solder material 25 from solder ball 20 is pulled into the hole 12 by its affinity for the wetting layer 14.

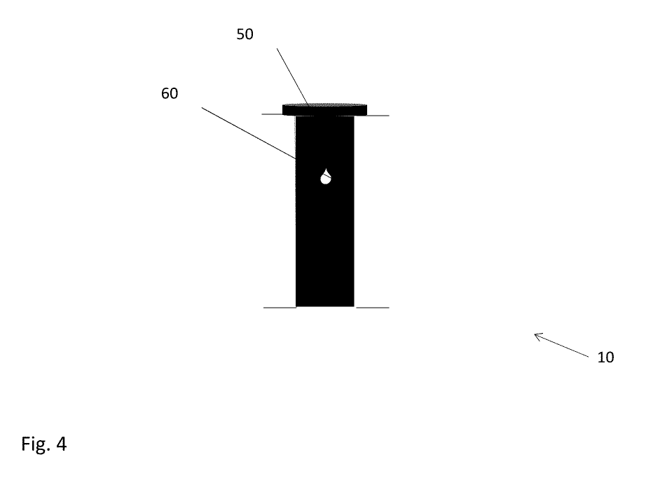

A “wetting” material or “wetting layer” should be understood to be a material for which the liquid solder has an affinity. Therefore, the wetting layer 14 may encourage the flow of the liquefied solder material into any areas where the wetting layer 14 has been deposited. Accordingly, after heating and melting, the solder ball 20 may melt and be drawn into the hole by affinity to the wetting layer 14. The condition of the through hole 12 and via through substrate via 10 may be as shown in FIG. 4, wherein the solder ball has melted and lost its shape, and the metal material 50 has flowed down into the via hole 12. There may nonetheless be a void 60 in the interior of the through hole 12.

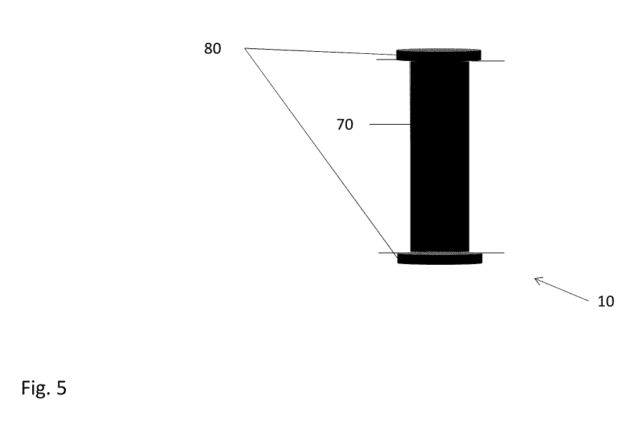

If a void 60 remains in the through hole, the solder may be “reflowed,” which is to say re-heated and re-melted in, for example, an oven or furnace. The liquid may then redistribute in the hole 12, forming a more continuous metal layer 70 and a smaller or nonexistent void. The continuous metal layer 70 may also constitute the through susbtrate via 70. The situation is as shown in FIG. 5. Accordingly, the process may include heating the solder ball and substrate in an oven, after heating the solder ball with a laser.

Accordingly, the method for forming through substrate vias using solder bumps may include forming a hole in the device substrate, forming a wetting layer in the hole, disposing a solder ball over the hole, and heating the substrate to the melting point of the solder ball. The process may include heating the solder ball until it melts, and forms an alloy with material of the wetting layer, whereupon forming the alloy, the alloy freezes in the hole, forming the through substrate via 10.

A bonding pad 80 may be provided on at least one end of the through substrate via 10. The bonding pad 80 may be of any material that can provide a low resistance connection between a voltage, current or signal source and the material 70 of the via. For example, a layer of gold may be deposited over the via 10 to provide this function.

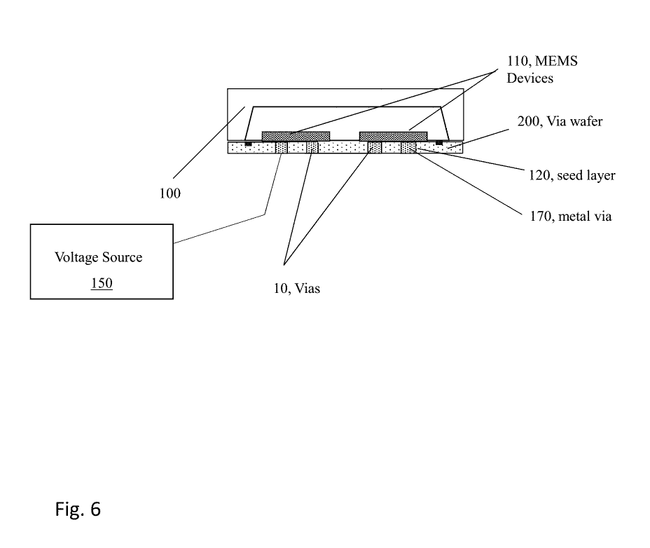

FIG. 6 is a schematic, cross sectional illustration of an application of the through substrate vias using solder bumps. FIG. 6 shows at least one microdevice, here a plurality of MEMS devices 110. Alternatively, the devices 110 may be integrated circuits (ICs). The MEMS devices or ICs 110 may be fabricated on a via wafer or substrate 200, into which a plurality of through substrate vias 10 have been formed according to the process set forth above. The plurality of devices 110 may be covered or protected with a lid wafer 100, which has a device cavity formed therein. The lid wafer may be bonded to the via wafer with, for example, a low temperature metal alloy bond. The device cavity may allow clearance for the plurality of microdevices 110 or for their movement. The lid wafer 100 may be hermetically bonded to the via wafer 200 and therefore may hold a vacuum or some preferred gaseous environment therein. The MEMS devices or integrated circuits 110 may be electrically coupled to a voltage, current or signal source 150, using the through substrate vias 10.

Accordingly, a method has been described, for forming a through substrate via in a device substrate, including forming a hole in the device substrate, forming a wetting layer in the hole, disposing a solder ball over the hole, and heating the substrate to the melting point of the solder ball. Within this method, the wetting layer may include at least one of gold, palladium, platinum, copper and tin, and may be formed by electroplating the wetting layer conformally over the hole. Alternatively, the forming the wetting layer may include forming the wetting layer with at least one of sputter deposition, chemical vapor deposition, and low pressure CVD, and plasma enhanced CVD. Within this method, the solder ball may include at least one of lead, tin, indium, silver, germanium, aluminum, gold, and copper.

Within this method, the disposing may include disposing the solder ball with a jet of forced air, and wherein the heating comprises heating the solder ball with a laser, and the heating may be performed in an oven. The laser may be coaxial with the jet of forced air. Alternatively, the heating may include heating the solder ball and substrate in an oven, after heating the solder ball with a laser. After the heating, the solder ball may melts and be drawn into the hole by affinity to the wetting layer. The solder ball may form an alloy with material of the wetting layer. Upon forming the alloy, the alloy may freeze in the hole, forming the through substrate via.

Within the method, disposing may comprise disposing the solder ball through a silk screen or with a pick-and-place machine. The wetting layer may be about 200 nm thick. The method may further comprise microfabricating at least one of a MEMS device and an integrated circuit electrically coupled to a voltage source by the through substrate via. The method may further comprise encapsulating the at least one device in a device cavity formed in a lid substrate, and further bonding the lid substrate to the device substrate with a low temperature metal alloy bond.

The through substrate via may have an aspect ratio of about 10, and a diameter of about 50 microns. The method may further comprise forming at least one bonding pad on at least one end of the through substrate via.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Furthermore, details related to the specific methods, dimensions, materials uses, shapes, fabrication techniques, etc. are intended to be illustrative only, and the invention is not limited to such embodiments. Descriptors such as top, bottom, left, right, back front, etc. are arbitrary, as it should be understood that the systems and methods may be performed in any orientation. Accordingly, the exemplary implementations set forth above, are intended to be illustrative, not limiting.

What is claimed is:

1. A method for forming a through substrate via in a device substrate, comprising:
forming a hole in the device substrate;
forming a wetting layer in the hole;
disposing a solder ball over the hole; and
heating the substrate to the melting point of the solder ball.

2. The method of claim 1, wherein the wetting layer comprises at least one of gold, palladium, platinum, copper and tin.

3. The method of claim 1, wherein forming the wetting layer comprises electroplating the wetting layer conformally over the hole.

4. The method of claim 1, wherein forming the wetting layer comprises forming the wetting layer with at least one of sputter deposition, chemical vapor deposition, and low pressure CVD, and plasma enhanced CVD.

5. The method of claim 1, wherein the solder ball comprises at least one of lead, tin, indium, silver, germanium, aluminum, gold, and copper.

6. The method of claim 1, wherein disposing comprises disposing the solder ball with a jet of forced air, and wherein the heating comprises heating the solder ball with a laser.

7. The method of claim 1, wherein the heating comprises heating the solder ball in an oven.

8. The method of claim 6, wherein the laser is coaxial with the jet of forced air.

9. The method of claim 8, wherein the heating comprises further heating the heating the solder ball and substrate in an oven, after heating the solder ball with a laser.

10. The method of claim 1, wherein after the heating, the solder ball melts and is drawn into the hole by affinity to the wetting layer.

11. The method of claim 10, wherein after melting, the solder ball forms an alloy with material of the wetting layer.

12. The method of claim 11, wherein upon forming the alloy, the alloy freezes in the hole, forming the through substrate via.

13. The method of claim 1, wherein disposing comprises disposing the solder ball through a silk screen.

14. The method of claim 1, wherein disposing comprises disposing the solder ball with a pick-and-place machine.

15. The method of claim 1, wherein the wetting layer is about 200 nm thick.

16. The method of claim 1, further comprising microfabricating at least one of a MEMS device and an integrated circuit electrically coupled to a voltage source by the through substrate via.

17. The method of claim 16, further comprising encapsulating the at least one device in a device cavity formed in a lid substrate.

18. The method of claim 17, further comprising bonding the lid substrate to the device substrate with a low temperature metal alloy bond.

19. The method of claim 1, wherein the through substrate via has an aspect ratio of about 10, and a diameter of about 50 microns.

20. The method of claim 1, further comprising forming at least one bonding pad on at least one end of the through substrate via.
